(19) United States
(12) Patent Application Publication
(10) Pub. No.: US 2025/0234453 A1
(43) Pub. Date: Jul. 17, 2025

(54) COMPOSITE MEMBER

(71) Applicant: Hitachi, Ltd., Tokyo (JP)

(72) Inventors: Daigo KOMESU, Tokyo (JP); Hiroshi MORITA, Tokyo (JP)

(73) Assignee: Hitachi, Ltd., Tokyo (JP)

(21) Appl. No.: 18/853,848

(22) PCT Filed: Feb. 6, 2023
(86) PCT No.: PCT/JP2023/003856

§ 371 Date: Oct. 3, 2024

(30) Foreign Application Priority Data
Jun. 23, 2022 (JP) 2022-101043

(51) Int. Cl. H05K 1/02; H05K 1/11

(52) U.S. Cl. CPC H05K 1/0256; H05K 1/111; H05K 2201/09036; H05K 2201/09045; H05K 2201/09063

(57) ABSTRACT

The present invention provides a composite member which includes an insulating spacer having a creepage surface withstand voltage higher than that of the related art even in an AC device in the atmosphere, can downsize a high-voltage device, and can improve insulation reliability. A composite member of the present invention includes a first conductor, a second conductor that is disposed at a predetermined interval from the first conductor and has a potential different from a potential of the first conductor, and an insulating spacer that supports the first conductor and the second conductor, in which an uneven portion having a length of 1/100 or more with respect to a length along a creepage surface of the insulating spacer is formed in a portion located between the first conductor and the second conductor in the insulating spacer.

### TECHNICAL FIELD

The present invention relates to a composite member, and more particularly to a composite member including a conductor and an insulating spacer and suitable for a high-voltage device such as a pattern substrate of a power module or the like.

### BACKGROUND ART

For example, in a high-voltage device such as a pattern substrate of a power module or the like, an insulating spacer is used to structurally support conductors having different potentials and prevent a short circuit (dielectric breakdown) between the conductors.

When such a structure is adopted, an electric field concentrates on a triple point where the conductor, the insulating spacer, and the space are in contact with each other, so that the triple point where the electric field concentrates becomes a weak point in terms of the insulation and becomes a starting point of discharge.

For this reason, discharge is likely to occur on a creepage surface of the insulating spacer and as compared with a case where insulation is secured only by a space between conductors where dielectric breakdown is likely to occur, in a case where insulation is secured on the creepage surface of the insulating spacer, discharge is likely to occur due to the electric field at the triple point, and it is necessary to take a large insulation distance in order to prevent the dielectric breakdown, which may lead to an increase in size of the device.

For this reason, PTL 1, which is a prior art document, describes production of a spacer provided with irregularities from 1 to 10 μm on a spacer creepage surface in order to suppress charging of the spacer, and an image drawing device using the spacer.

According to PTL 1, when a DC voltage is applied in vacuum, electrons can be confined in recesses of the irregularities formed on the spacer creepage surface, and there is an effect of suppressing charging.

### CITATION LIST

### Patent Literature

PTL 1: JP 2000-243274 A

### SUMMARY OF INVENTION

### Technical Problem

However, in the “spacer provided with the irregularities from 1 to 10 μm on the spacer creepage surface” described in PTL 1 described above, since the purpose is to suppress charging in vacuum, it is insufficient for relaxation of a structural electric field, and in an AC device in the atmosphere having a low influence of charging, a sufficient effect for suppressing partial discharge and dielectric breakdown may not be obtained from the viewpoint of insulation.

The present invention has been made in view of the above points, and an object of the present invention is to provide a composite member which includes an insulating spacer having a creepage surface withstand voltage higher than that of the related art even in the AC device in the atmosphere, can downsize a high-voltage device, and can improve insulation reliability.

### Solution to Problem

In order to achieve the above object, a composite member of the present invention includes a first conductor, a second conductor that is disposed at a predetermined interval from the first conductor and has a potential different from a potential of the first conductor, and an insulating spacer that supports the first conductor and the second conductor, in which an uneven portion having a length of 1/100 or more with respect to a length along a creepage surface of the insulating spacer is formed in a portion located between the first conductor and the second conductor in the insulating spacer.

### Advantageous Effects of Invention

According to the invention, an insulating spacer having a creepage surface withstand voltage higher than the conventional one even in an AC device in the atmosphere is provided, a high-voltage device can be downsized, and insulation reliability can be improved.

### BRIEF DESCRIPTION OF DRAWINGS

FIG. 1 is a sectional view illustrating a first embodiment of a composite member of the present invention.

FIG. 2 is a characteristic diagram showing a result of calculating, by electric field analysis, a reduction effect of a creepage surface electric field by a structure of an uneven portion in the first embodiment of the composite member of the present invention illustrated in FIG. 1.

FIG. 3 is a sectional view illustrating a second embodiment of the composite member of the present invention.

FIG. 4 is a sectional view illustrating a third embodiment of the composite member of the present invention.

FIG. 5 is a sectional view illustrating a fourth embodiment of the composite member of the present invention.

FIG. 6 is a sectional view illustrating a fifth embodiment of the composite member of the present invention.

FIG. 7 is a sectional view illustrating a sixth embodiment of the composite member of the present invention.

FIG. 8 is a sectional view illustrating a seventh embodiment of the composite member of the present invention.

FIG. 9 is a sectional view illustrating an eighth embodiment of the composite member of the present invention.

FIG. 10 is a perspective view illustrating an example of an insulating spacer as a ninth embodiment of the composite member of the present invention.

### Description of Embodiments

Hereinafter, the composite member of the present invention will be described based on the illustrated embodiments. In the following embodiments, the same reference numerals are used for the same components, and repeated description thereof will be omitted.

### First Embodiment

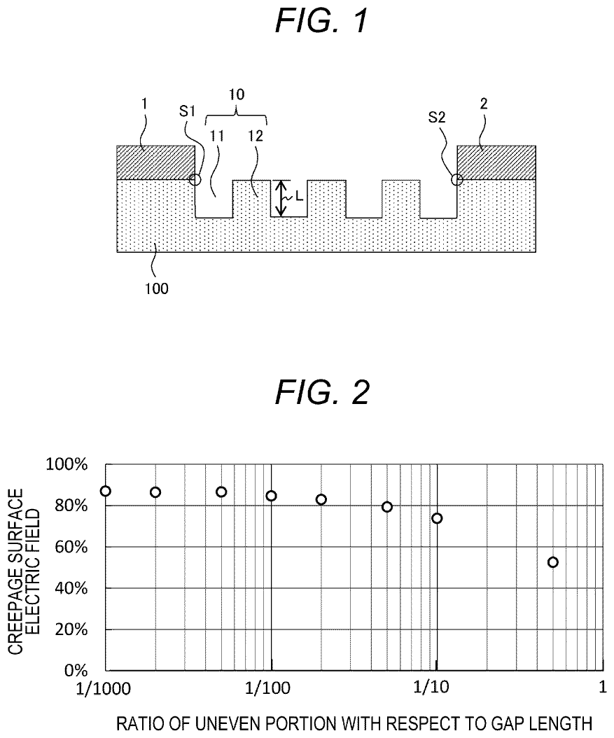

A first embodiment of a composite member of the present invention will be described with reference to FIG. 1. FIG. 1 is a sectional view of the composite member in the present embodiment.

As illustrated in FIG. 1, the composite member of the present embodiment roughly includes a first conductor 1, a second conductor 2 having a potential different from that of the first conductor 1, and an insulating spacer 100 that supports the first and second conductors 1 and 2.

In the composite member of the present embodiment, in order to secure insulation between the first and second conductors 1 and 2, uneven portions 10 each having a square shape and including a recess 11 and a protrusion 12 are formed in a portion located between the first conductor 1 and the second conductor 2 on the insulating spacer 100, and the uneven portion 10 is formed to have a length of 1/100 or more with respect to a length along a creepage surface of the insulating spacer 100.

That is, as illustrated in FIG. 1, the length (L) of the uneven portion 10 is formed to be 1/100 or more with respect to the length along the creepage surface of the insulating spacer 100.

As the material of the insulating spacer 100, general-purpose plastics such as an acrylonitrile butadiene styrene (ABS) resin, an epoxy resin, a nylon resin, polyphenylene sulfide (PPS), and polycarbonate, ceramics such as alumina, SiC, and SiN, and the like are assumed.

In addition, a composite material in which a filler is added to these resins as a main agent may be used. Furthermore, these materials may be manufactured by a 3D printer according to processing accuracy. Note that the 3D printer here may be any of a thermal fusion lamination type, an inkjet type, a stereolithography type, a powder type, a sheet lamination type, and the like.

The first and second conductors 1 and 2 are disposed and supported on the insulating spacer 100, and an electrode to which a high voltage is applied or an electrode electrically connected to the ground, or a metallized metal pattern wiring on which a metal is vapor-deposited, or the like is assumed.

An electric field concentrates on a first triple point S1 where the insulating spacer 100 is in contact with the first conductor 1 and the recess 11 and on a second triple point S2 where the insulating spacer 100 is in contact with the second conductor 2 and the recess 11. When a potential difference between the first conductor 1 and the second conductor 2 increases, local discharge (partial discharge) occurs on the creepage surface of the insulating spacer 100 near the first and second conductors 1 and 2. In order to suppress the local discharge (partial discharge) and improve a withstand voltage of the creepage surface of the insulating spacer 100, it is important to reduce the electric fields at the first and second triple points S1 and S2.

In the composite member of the present embodiment, the insulating spacer 100 includes the uneven portion 10 in order to control the electric field on the creepage surface, and in particular, in order to reduce the creepage surface electric fields at the first and second triple points S1 and S2, it is desirable that the recess 11 is formed on the insulating spacer 100 on the sides of the first and second triple points S1 and S2 between the first and second conductors 1 and 2 and the insulating spacer 100.

As a result, the creepage surface with the first and second triple points S1 and S2 between the insulating spacer 100 and the first and second conductors 1 and 2 as starting points can be made horizontal with respect to a space between the first conductor 1 and the second conductor 2 (the first triple point S1 where the first conductor 1 is in contact with the insulating spacer 100 and the recess 11, and the second triple point S2 where the second conductor 2 is in contact with the insulating spacer 100 and the recess 11 are horizontal in a vertical direction), and the creepage surface electric field can be relaxed.

When the uneven portion 10 is extremely small (short), the effect of electric field reduction is low, and improvement of the partial discharge voltage cannot be expected. Therefore, as described above, the length (L) of the uneven portion 10 effective for improvement of the partial discharge voltage is desirably 1/100 or more with respect to the length (distance between electrodes) along the creepage surface of the insulating spacer 100.

FIG. 2 shows a result of calculating, by electric field analysis, the reduction effect of the creepage surface electric field by the structure of the uneven portion 10 in the composite member of the present embodiment.

The horizontal axis in FIG. 2 represents the size of the uneven portion 10 in a ratio in a case where the insulation distance is 1 when there is no uneven portion 10. The vertical axis in FIG. 2 represents the electric field in a case where the uneven portion 10 is present in a case where the electric field is 100% when there is no uneven portion 10.

As can be seen from FIG. 2, the electric field reduction effect is small when the uneven portion 10 is small, and the electric field can be greatly reduced when the uneven portion 10 has a length of about 1/100 or more. Therefore, the length (L) of the uneven portion 10 is preferably from 1/100 to 1 with respect to the length (distance between electrodes) along the creepage surface of the insulating spacer 100.

Examples of the high-voltage device to which the composite member of the present embodiment is applied include a pattern substrate such as a power module.

It is necessary to secure insulation on the creepage surface of the substrate with respect to the potential difference between the pattern wirings of the pattern substrate, but by adopting the composite member of the present embodiment, the insulation distance of the creepage surface can be increased at the same distance between the pattern wirings, the electric field can be relaxed, and the withstand voltage can be improved.

According to the present embodiment as described above, the electric fields generated on the creepage surface of the insulating spacer 100 near the first and second conductors 1 and 2 can be alleviated, and the high-voltage device can be downsized and the insulation reliability can be improved by providing the insulating spacer 100 having the creepage surface withstand voltage higher than the conventional one even in the AC device in the atmosphere.

### Second Embodiment

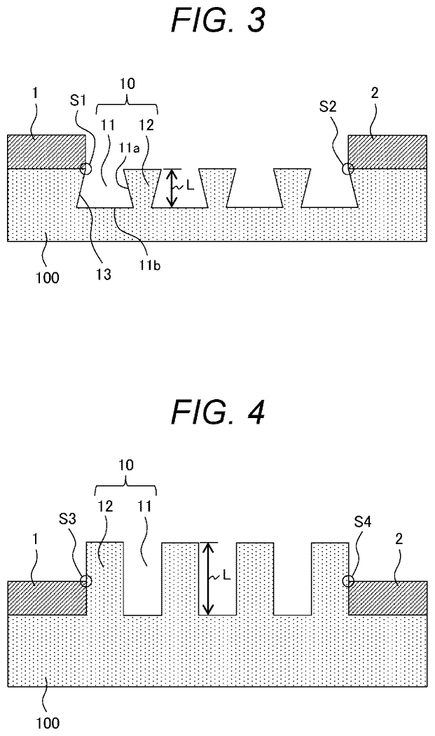

A second embodiment of the composite member of the present invention will be described with reference to FIG. 3.

In the first embodiment illustrated in FIG. 1, the uneven portion 10 having the square shape is provided on the surface of the insulating spacer 100. However, the present embodiment illustrated in FIG. 3 is different from the first embodiment in that a tapered portion 13 in which the recess 11 widens toward a bottom portion 11b of the recess 11 is formed on a side portion 11a of the recess 11 of the uneven portion 10 of the insulating spacer 100, and the recess 11 and the protrusion 12 are configured to have a substantially triangular sectional shape.

Also in the present embodiment, as illustrated in FIG. 3, the length (L) of the uneven portion 10 is formed to be 1/100 or more with respect to the length along the creepage surface of the insulating spacer 100. Other configurations are similar to those of the first embodiment.

Normally, in the electric field on the creepage surface of the insulating spacer 100, an equipotential line formed by the first conductor 1, the second conductor 2, and the insulating spacer 100 intersects the creepage surface of the insulating spacer 100, whereby the creepage surface electric field is formed.

Therefore, by providing the tapered portion 13 on the uneven portion 10 of the insulating spacer 100 and forming the length (L) of the uneven portion 10 to be 1/100 or more with respect to the length along the creepage surface of the insulating spacer 100, the creepage surface of the insulating spacer 100 can be brought close to parallel to the equipotential line formed between the first conductor 1 and the second conductor 2, and the creepage surface electric field of the insulating spacer 100 can be reduced.

Even with such a configuration of the present embodiment, the same effects as those of the first embodiment can be obtained.

### Third Embodiment

A third embodiment of the composite member of the present invention will be described with reference to FIG. 4.

The third embodiment illustrated in FIG. 4 is different from the first embodiment in that the protrusion 12 in the uneven portion 10 having a rectangular shape on the surface of the insulating spacer 100 described in the first embodiment is formed on the insulating spacer 100 on the first triple point S3 side where the triple point between the first conductor 1 and the insulating spacer 100 is in contact with the atmosphere and on the second triple point S4 side where the second conductor 2 is in contact with the insulating spacer 100 and the atmosphere, and the protrusion 12 is higher than the first triple point S3 and the second triple point S4.

Also in the present embodiment, as illustrated in FIG. 4, the length (L) of the uneven portion 10 is formed to be 1/100 or more with respect to the length along the creepage surface of the insulating spacer 100. Other configurations are similar to those of the first embodiment.

Normally, in a case where insulation between conductors is secured in the high-voltage device, it is necessary to prevent both partial discharge and dielectric breakdown, and with respect to the partial discharge, it is important to alleviate electric field concentration near an electrode. With respect to the dielectric breakdown, it is important to lengthen a progress path of the discharge in addition to the relaxation of the electric field. The progress path of the discharge progresses along a line of electric force formed between the electrodes.

In the present embodiment, the protrusion 12 is formed on the insulating spacer 100 on the first triple point S3 side where the first conductor 1 and the insulating spacer 100 are in contact with the atmosphere and on the second triple point S4 side where the second conductor 2 is in contact with the insulating spacer 100 and the atmosphere, and the protrusion 12 is higher than the first triple point S3 and the second triple point S4.

With such a configuration, the line of electric force formed between the first conductor 1 and the second conductor 2 intersects with the protrusion 12, and the progress of discharge can be suppressed.

Even with such a configuration of the present embodiment, the same effects as those of the first embodiment can be obtained.

### Fourth Embodiment

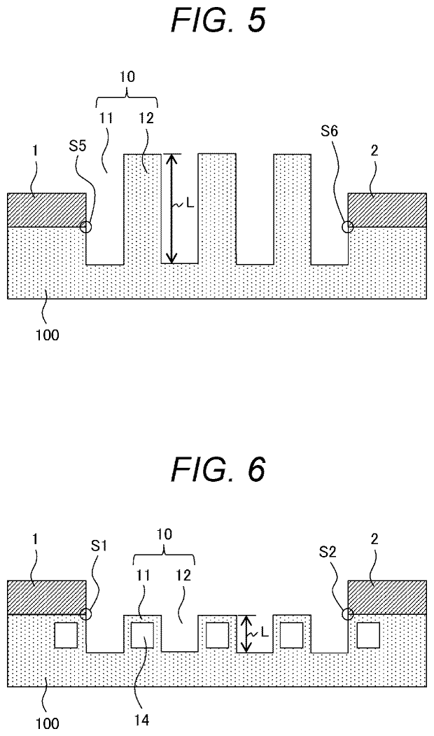

A fourth embodiment of the composite member of the present invention will be described with reference to FIG. 5.

In the fourth embodiment illustrated in FIG. 5, a recess 11 lower than first and second triple points S5 and S6 is formed adjacent to each of the first triple point S5 where the insulating spacer 100 is in contact with the first conductor 1 and the recess 11 and the second triple point S6 where the insulating spacer 100 is in contact with the second conductor 2 and the recess 11, and a protrusion 12 higher than the first and second triple points S5 and S6 is formed adjacent to the recess 11.

Also in the present embodiment, as illustrated in FIG. 5, the length (L) of the uneven portion 10 is formed to be 1/100 or more with respect to the length along the creepage surface of the insulating spacer 100. Other configurations are similar to those of the first embodiment.

Even with such a configuration of the present embodiment, it is needless to say that both the partial discharge and the dielectric breakdown can be suppressed, and the same effects as those of the first embodiment can be obtained.

### Fifth Embodiment

A fifth embodiment of the composite member of the present invention will be described with reference to FIG. 6.

In the first and second embodiments described above, the uneven portion 10 is formed on the surface of the insulating spacer 100, and the length (L) of the uneven portion 10 is formed to be 1/100 or more with respect to the length along the creepage surface of the insulating spacer 100, whereby the electric field near the electrode is reduced.

In order to reduce the electric field, it is desirable that the uneven portion 10 is larger. However, in a case where the size of the uneven portion 10 is limited due to factors other than insulation such as restrictions of the high-voltage device, the electric field reduction effect may not be sufficiently obtained.

Therefore, in the present embodiment, as illustrated in FIG. 6, an air layer 14 is provided in the protrusion 12 inside the insulating spacer 100.

Also in the present embodiment, as illustrated in FIG. 6, the length (L) of the uneven portion 10 is formed to be 1/100 or more with respect to the length along the creepage surface of the insulating spacer 100. Other configurations are similar to those of the first embodiment.

In general, in composite insulation including two types of insulators such as an insulator and a space different from each other, an electric field concentrates on a medium having a lower dielectric constant as a difference in dielectric constant between the insulator and the space is larger. In particular, when compared between the solid insulator and air, the dielectric constant and the dielectric breakdown voltage of air are lower than those of the solid insulator, and thus the electric field tends to concentrate and discharge tends to occur.

Therefore, the air layer 14 is provided in the protrusion 12 inside the insulating spacer 100, and the length (L) of the uneven portion 10 is formed to be 1/100 or more with respect to the length along the creepage surface of the insulating spacer 100, so that the dielectric constant difference between the solid insulator and the air is reduced, and the electric field concentration on the air is alleviated, so that the insulating performance as the composite insulation can be enhanced.

In addition, depending on the shape and configuration of the conductor, the air layer 14 may be provided only in the uneven portion 10 located in a portion close to one conductor or portions close to both conductors, and the uneven portion 10 not including the air layer 14 may be provided.

In the present embodiment, as illustrated in FIG. 6, by disposing the air layer 14 on the protrusion 12 inside the insulating spacer 100, the dielectric constant of the solid insulator can be made close to the space, and the electric field in the space is reduced, so that the discharge can be suppressed.

Even with such a configuration of the present embodiment, the same effects as those of the first embodiment can be obtained.

### Sixth Embodiment

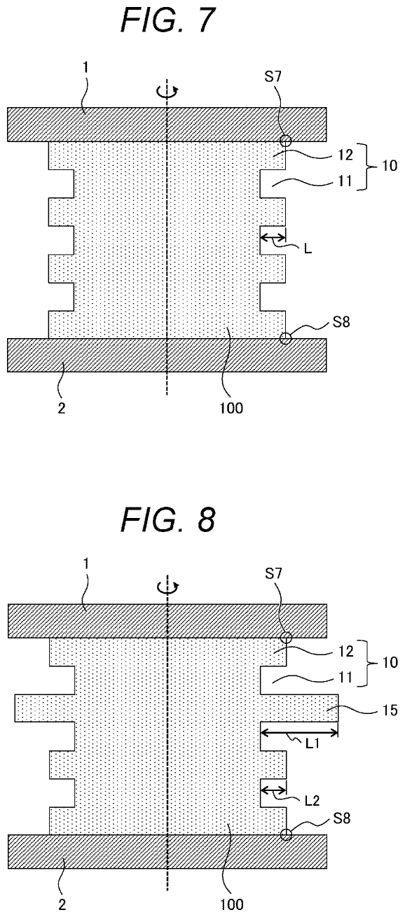

A sixth embodiment of the composite member of the present invention will be described with reference to FIG. 7.

In the first embodiment described above, the first and second conductors 1 and 2 are disposed on the surface of the insulating spacer 100. However, the present embodiment illustrated in FIG. 7 is different from the first to fifth embodiments in that the insulating spacer 100 is sandwiched between the upper and lower sides of the first conductor 1 and the second conductor 2, the protrusion 12 is provided with respect to a first triple point S7 where the first conductor 1 is in contact with the insulating spacer 100 and the atmosphere, and a second triple point S8 where the second conductor 2 is in contact with the insulating spacer 100 and the atmosphere, and the recess 11 is formed adjacent to the protrusion 12 on the inner side of the insulating spacer 100 than the triple points S7 and S8.

Also in the present embodiment, as illustrated in FIG. 7, the length (L) of the uneven portion 10 is formed to be 1/100 or more with respect to the length along the creepage surface of the insulating spacer 100.

As illustrated in the first embodiment of FIG. 1, when the first and second conductors 1 and 2 are disposed on the surface of the insulating spacer 100, the recess 11 is provided with respect to the first and second triple points S1 and S2 between the insulating spacer 100 and the first and second conductors 1 and 2, so that the creepage surface of the insulating spacer 100 at the first and second triple points S1 and S2 is set in a perpendicular direction with respect to a space between the first and second conductors 1 and 2 (the creepage surface of the insulating spacer 100 at the first triple point S1 where the insulating spacer 100 is in contact with the first conductor 1 and the recess 11 and the second triple point S2 where the insulating spacer 100 is in contact with the second conductor 2 and the recess 11 is in a perpendicular (vertical) direction to the space between the first and second conductors 1 and 2.), thereby reducing the electric field on the creepage surface.

In the case of the configuration of the present embodiment, even when any of the first and second conductors 1 and 2 are in contact with the recess 11 and the protrusion 12, the creepage surface is parallel to the direction between the first and second conductors 1 and 2 (that is, the creepage surface is parallel to the vertical direction between the first and second conductors 1 and 2.). When the uneven portion 10 is continuous, the recess 11 is the space, and the protrusion 12 is the solid insulator, so that the electric field concentrates on the recess 11 having the low dielectric constant.

Therefore, in the configuration of the present embodiment illustrated in FIG. 7, the protrusion 12 having the low electric field is disposed to be in contact with the first and second conductors 1 and 2, the recess 11 is disposed adjacent to the protrusion 12 inside the insulating spacer 100 than the first and second triple points S7 and S8, and the length (L) of the uneven portion 10 is formed to be 1/100 or more with respect to the length along the creepage surface of the insulating spacer 100, so that the electric field at the triple points S7 and S8 can be alleviated and the discharge can be suppressed.

According to the present embodiment as described above, the electric fields generated on the creepage surface of the insulating spacer 100 near the first and second conductors 1 and 2 can be alleviated, and the high-voltage device can be downsized and the insulation reliability can be improved by providing the insulating spacer 100 having the creepage surface withstand voltage higher than the conventional one even in the AC device in the atmosphere.

### Seventh Embodiment

A seventh embodiment of the composite member of the present invention will be described with reference to FIG. 8.

The seventh embodiment illustrated in FIG. 8 has a structure in which a protrusion 15 higher than the protrusion 12 of the uneven portion 10 formed on the first triple point S7 side where the first conductor 1 is in contact with the insulating spacer 100 and the atmosphere and on the second triple point S8 side where the second conductor 2 is in contact with the insulating spacer 100 and the atmosphere and higher than the first and second triple points S7 and S8 on the outer side is formed in the middle of the insulating spacer 100 at a position farther from the first and second conductors 1 and 2 than the protrusion 12.

In the present embodiment, the lengths (L1 and L2) of the uneven portions 10 are formed to be 1/100 or more with respect to the length along the creepage surface of the insulating spacer 100. Other configurations are similar to those of the sixth embodiment.

As a result, since the protrusion 15 higher than the first and second triple points S7 and S8 on the outer side is provided, the progress of the discharge generated from the first and second triple points S7 and S8 can be suppressed simultaneously with the electric field relaxation of the first and second triple points S7 and S8.

An example of the high-voltage device in the present embodiment includes a high-voltage generation device. In the high-voltage generation device, a high-voltage terminal to which a desired voltage is applied is electrically insulated from a housing connected to a ground potential by the insulating spacer and is mechanically supported.

By providing the protrusions 12 and 15 as in the present embodiment on the creepage surface of the insulating spacer, electric fields at portions of the first and second triple points S7 and S8 can be relaxed, and the withstand voltage can be improved.

Even with such a configuration of the present embodiment, the same effects as those of the sixth embodiment can be obtained.

### Eighth Embodiment

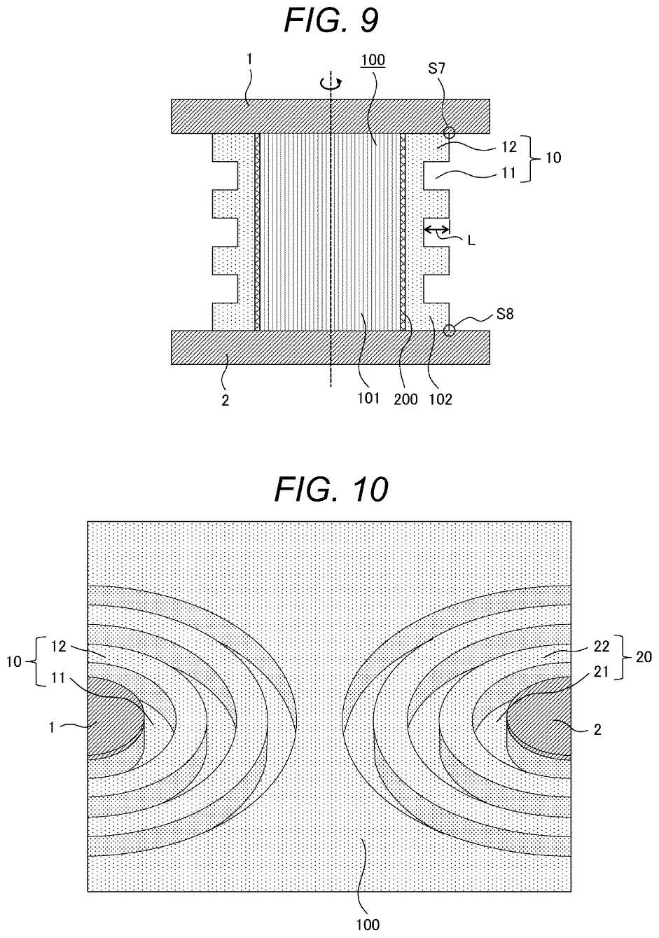

An eighth embodiment of the composite member of the present invention will be described with reference to FIG. 9.

The composite member of the present embodiment illustrated in FIG. 9 is different from the sixth embodiment illustrated in FIG. 7 in that the insulating spacer 100 includes a first insulating spacer 101 including no uneven portion 10 and a second insulating spacer 102 including processed uneven portion 10, and the first insulating spacer 101 including no uneven portion 10 and the second insulating spacer 102 including processed uneven portion 10 are fixed to each other with an adhesive 200.

Also in the present embodiment, the length (L) of the uneven portion 10 is formed to be 1/100 or more with respect to the length along the creepage surface of the insulating spacer 100.

Normally, the insulating spacer 100 plays both the role of insulation and the role of supporting the conductor, but when the material of the insulating spacer 100 is selected from the viewpoint of mechanical strength or the like, processing of the uneven portion 10 may be difficult.

Therefore, in the present embodiment illustrated in FIG. 9, the first insulating spacer 101 including no uneven portion 10 in which processing of the insulating spacer 100 is difficult and the second insulating spacer 102 including a surface on which processing of the uneven portion 10 can be performed, and the first insulating spacer 101 including no uneven portion 10 and the second insulating spacer 102 including the surface on which the uneven portion 10 is processed are fixed to each other with an adhesive 200.

According to such a configuration of the present embodiment, not only the same effects as those of the sixth embodiment can be obtained, but also the effect that the uneven portion 10 can be formed on the creepage surface of the insulating spacer 100 can be obtained even when a material that is difficult to process is selected as the insulating spacer 100.

It goes without saying that the configuration of the present embodiment can be applied to the first to seventh embodiments.

### Ninth Embodiment

As a ninth embodiment of the composite member of the present invention, details of the insulating spacer 100 will be described with reference to FIG. 10.

The insulating spacer 100 of the present embodiment illustrated in FIG. 10 illustrates a three-dimensional structure of the first and second conductors 1 and 2 and the insulating spacer 100.

As illustrated in FIG. 10, the uneven portion 10 adjacent to the first conductor 1 has a structure along the first triple point S1 between the first conductor 1 and the insulating spacer 100, and an uneven portion 20 including a recess 21 and a protrusion 21 adjacent to the second conductor 2 has a structure along the second triple point S2 between the second conductor 2 and the insulating spacer 100.

In a case where the electric fields at the first and second triple points S1 and S2 between the first and second conductors 1 and 2 and the insulating spacer 100 are to be relaxed, it is desirable that the uneven portions 10 and 20 be similarly configured in accordance with the shapes of the first and second conductors 1 and 2. For example, in a case where the conductor shapes are different between the first and second conductors 1 and 2 and are asymmetric, it is desirable that the uneven portion 10 also has an asymmetric structure in accordance with the shapes of the first and second conductors 1 and 2.

Note that the present invention is not limited to the above-described embodiment, and includes various modifications.

For example, the above-described embodiments have been described in detail for easy understanding of the present invention, and are not necessarily limited to those having all the described configurations. In addition, a part of the configuration of a certain embodiment can be replaced with the configuration of another embodiment, and the configuration of another embodiment can be added to the configuration of a certain embodiment. In addition, it is possible to add, delete, and replace another configuration for a part of the configuration of each embodiment.

### REFERENCE SIGNS LIST

1 first conductor
2 second conductor
10, 20 uneven portion
11, 21 recess
11a side portion of recess
11b bottom portion of recess
12, 15, 22 protrusion
13 tapered portion
14 air layer
100 insulating spacer
101 first insulating spacer
102 second insulating spacer
200 adhesive

1. A composite member comprising:
a first conductor;
a second conductor that is disposed at a predetermined interval from the first conductor and has a potential different from a potential of the first conductor; and
an insulating spacer configured to support the first conductor and the second conductor,
wherein an uneven portion having a length of 1/100 or more with respect to a length along a creepage surface of the insulating spacer is formed in a portion located between the first conductor and the second conductor in the insulating spacer.

2. The composite member according to claim 1, wherein a recess of the uneven portion is formed on the insulating spacer on a first triple point side where the insulating spacer is in contact with the first conductor and the recess of the uneven portion and on a second triple point side where the insulating spacer is in contact with the second conductor and the recess of the uneven portion.

3. The composite member according to claim 2, wherein a creepage surface with the first and second triple points between the insulating spacer and the first and second conductors as starting points is horizontal in a vertical direction with respect to a space between the first conductor and the second conductor.

4. The composite member according to claim 3, wherein the uneven portion has a square shape or a rectangular shape.

5. The composite member according to claim 3, wherein the uneven portion includes a tapered portion formed on a side of the recess.

6. The composite member according to claim 1, wherein a protrusion of the uneven portion is formed on the insulating spacer on a first triple point side where the insulating spacer is in contact with the first conductor and the atmosphere and on a second triple point side where the insulating spacer is in contact with the second conductor and the atmosphere.

7. The composite member according to claim 6, wherein the protrusion of the uneven portion is higher than the first triple point and the second triple point.

8. The composite member according to claim 1, wherein a recess of the uneven portion lower than the first and second triple points is formed adjacent to each of a first triple point where the insulating spacer is in contact with the first conductor and the recess of the uneven portion and a second triple point where the insulating spacer is in contact with the second conductor and the recess of the uneven portion, and a protrusion of the uneven portion higher than the first and second triple points is formed adjacent to the recess of the uneven portion.

9. The composite member according to claim 1, wherein an air layer is provided inside the insulating spacer and at least in a protrusion of the uneven portion.

10. The composite member according to claim 1, wherein the insulating spacer is disposed between upper and lower sides of the first conductor and the second conductor, a protrusion of the uneven portion is formed on a first triple point side where the first conductor is in contact with the insulating spacer and atmosphere and on a second triple point side where the second conductor is in contact with the insulating spacer and atmosphere, and a recess of the uneven portion is formed adjacent to the protrusion and deeper inside the insulating spacer than the first and second triple points.

11. The composite member according to claim 10, wherein a protrusion higher than the protrusions formed on the first and second triple point sides and higher than the first and second triple points is formed in the middle of the insulating spacer.

12. The composite member according to claim 1, wherein the insulating spacer includes a first insulating spacer disposed inside the insulating spacer and including no uneven portion, and a second insulating spacer disposed outside the first insulating spacer and including a surface on which the uneven portion is processed, and the first insulating spacer and the second insulating spacer are fixed to each other with an adhesive.
